(19) United States
(12) Patent Application Publication
(10) Pub. No.: US 2026/0169390 A1
(43) Pub. Date: Jun. 18, 2026

(54) APPARATUS AND METHODS FOR REMOVING PHOTORESIST AND POLYMER COATINGS

(71) Applicant: Yield Engineering Systems, Inc., Fremont, CA (US)

(72) Inventors: M Ziaul Karim, Fremont, CA (US); Venugopal Govindarajulu, Fremont, CA (US); Kevin McGillivray, Valencia, CA (US)

(73) Assignee: Yield Engineering Systems, Inc., Fremont, CA (US)

(21) Appl. No.: 18/978,346

(22) Filed: Dec. 12, 2024

(51) Int. Cl. G03F 7/42

(52) U.S. Cl. CPC G03F 7/425; G03F 7/426

(57) ABSTRACT

A system for removing polymeric coatings from substrates includes a wet processing tank capable of holding a liquid chemical. The tank is configured to accommodate at least one substrate with a polymer-coated surface, ensuring that at least part of the coating is immersed in the chemical. Additionally, the system features multiple nozzles positioned within the tank, also immersed in the chemical, which are designed to spray fluid streams of the chemical onto the substrate's surface to facilitate the removal of the polymeric coating.

### TECHNICAL FIELD

The present disclosure relates to an apparatus and method for removing photoresist and polymer coatings from a surface of a semiconductor substrate.

### BACKGROUND

Semiconductor fabrication processes often involve the use of several polymer layers. For instance, photoresist (PR) (or dry film resist (DFR)) layers are employed in the creation of interconnect structures, such as traces, contact pads, bumps, and vias. These photoresist or dry film resist layers are applied and developed on the surface of a semiconductor substrate during the formation of these structures. In a typical process, after the interconnect structures are formed, the photoresist (or dry film resist) layer is removed (or stripped), and the semiconductor surface is cleaned. Removing or stripping the photoresist layer is usually accomplished through spray or immersion techniques.

An immersion technique typically involves submerging the coated substrate in a bath containing a liquid solution that dissolves or loosens the photoresist. The solution, often a chemical stripper or solvent, breaks down the photoresist material, allowing it to be lifted off the surface of the substrate. A spray technique involves spraying a chemical stripper or solvent onto the coated surface. The solvent dissolves or softens the photoresist, allowing it to be lifted off the surface. After the photoresist is removed, the substrate is rinsed with a solvent or water to remove any residual chemicals, leaving the substrate clean for subsequent processes. Stripping photoresist using immersion and spray techniques presents several challenges. For instance, as photoresist hardens during curing and other pre-processes, removing the hardened photoresist becomes difficult. Additionally, the disposal and proper handling of the stripped photoresist pose challenges, leading to reduced bath life and increased cycle times. These issues contribute to higher costs for effective and efficient photoresist removal. The systems and methods of the current disclosure may alleviate at least some of these deficiencies.

### SUMMARY

Several embodiments of apparatus, systems, and methods for removing photoresist and polymer coatings (collectively referred herein as polymeric coating) from a substrate surface are disclosed. It is to be understood that both the foregoing general description and the following detailed description are exemplary and explanatory only. As such, the scope of the disclosure is not limited solely to the disclosed embodiments. Instead, it is intended to cover such alternatives, modifications and equivalents within the spirit and scope of the disclosed embodiments. Persons skilled in the art would understand how various changes, substitutions and alterations can be made to the disclosed embodiments without departing from the spirit and scope of the disclosure.

In one embodiment, system for removing a polymeric coating from a substrate is disclosed. The system includes a wet processing tank configured to contain a chemical in liquid form. The wet processing tank is configured to receive at least one substrate having a surface with a polymeric coating such that at least a portion of the polymeric coating is immersed in the chemical. The system may also include a plurality of nozzles positioned in the tank and configured to be immersed in the chemical. Each nozzle of the plurality of nozzles is configured to direct a fluid stream of the chemical on the surface to remove at least a portion of the polymeric coating from the surface.

In another embodiment, a method of removing a polymeric coating from a substrate is disclosed. The method includes positioning at least one substrate having a surface with a polymeric coating in a wet processing tank containing a chemical in liquid form such that at least a portion of the polymeric coating is immersed in the chemical and is positioned proximate a plurality of nozzles positioned in the tank. The method may also include directing a fluid stream of the chemical on the surface through the plurality of nozzles to remove at least a portion of the polymeric coating from the surface.

### BRIEF DESCRIPTION OF THE DRAWINGS

The accompanying drawings, which are incorporated in and constitute a part of this disclosure, illustrate simplified schematic representations of exemplary embodiments. Together with the description, these figures are used to explain the disclosed principles. In these drawings, where appropriate, reference numerals illustrating like structures, components, materials, and/or elements in different figures are labeled similarly. It should be noted that the figures are only simplified schematics of exemplary embodiments and there can be many features and variations not shown in these figures. It is understood that various combinations of the structures, components, and/or elements, other than those specifically shown, are contemplated and are within the scope of the present disclosure. Specifically, the scope of the current disclosure is defined by the claims and not by the specific embodiments illustrated in the figures.

For simplicity and clarity of illustration, the figures depict the general structure of the various described embodiments. Details of well-known components or features may be omitted to avoid obscuring other features, since these omitted features are well-known to those of ordinary skill in the art. Further, elements in the figures are not necessarily drawn to scale. The dimensions of some features may be exaggerated relative to other features to improve understanding of the exemplary embodiments. One skilled in the art would appreciate that the features in the figures are not necessarily drawn to scale and, unless indicated otherwise, should not be viewed as representing proportional relationships between features in a figure. Additionally, even if it is not specifically mentioned, aspects described with reference to one embodiment or figure may also be applicable to, and may be used with, other embodiments or figures.

FIGS. 1A and 1B are schematic illustrations of an exemplary coating removal system, consistent with the current disclosure;

FIG. 2A illustrates a nozzle spraying a polymer-coated surface of a substrate with a chemical in liquid form, consistent with the current disclosure;

FIG. 2B illustrates a nozzle spraying a polymer-coated surface of a substrate with a chemical in aerosol form, consistent with the current disclosure;

FIG. 3 illustrates an exemplary nozzle, consistent with the current disclosure;

FIGS. 4A and 4B are a side view and a top view, respectively, of a tank with an array of nozzles, consistent with the current disclosure;

FIG. 5 is a schematic illustrations of an exemplary multi-tank coating removal system, consistent with the current disclosure;

FIGS. 6A and 6B are exemplary method of removing a polymeric coating from a substrate surface, consistent with the current disclosure.

### DETAILED DESCRIPTION

All relative terms such as “about,” “substantially,” “approximately,” etc., indicate a possible variation of ±10% (unless noted otherwise or another variation is specified). For example, a feature disclosed as being about “ [symbol] ” units long (wide, thick, etc.) may vary in length from ( [symbol] −0.1 [symbol] ) to ( [symbol] +0.1 [symbol] ) units. Similarly, a temperature within a range of about 100-150° C. can be any temperature between (100-10%) and (150 +10%). Further, a range described as varying from (or between) 100-150, includes the endpoints (i.e., 100 and 150). In some cases, the specification provides context to the relative terms used. For example, substantially linear refers to a relationship or trend that closely follows a straight line, but may exhibit minor deviations from perfect linearity due to practical constraints or real-world limitations. These deviations can arise from factors such as measurement inaccuracies, inherent variability in the system, or external influences that cause slight fluctuations. In many cases, the variation is so small that it does not significantly impact the overall behavior or outcome, but it acknowledges that perfect linearity is difficult to achieve in practice. Thus, in this disclosure, relative terms are used to allow for some degree of variation resulting from practical, real-world, reasons. For example, a substantially linear geometry allows for some degree of non-linearity while still maintaining a general straight-line trend.

As used herein, unless specifically stated otherwise, the term “or” encompasses all possible combinations, except where infeasible. For example, if it is stated that a component (method, etc.) can comprise A or B, then, unless specifically stated otherwise or infeasible, the component can comprise A, or B, or A and B. As a second example, if it is stated that a component can comprise A, B, or C, then, unless specifically stated otherwise or infeasible, the component can comprise A, or B, or C, or A and B, or A and C, or B and C, or A and B and C.

In this disclosure, the term “polymeric coating” is used to collectively refer to polymer coatings and photoresist coatings. In other words, the term polymeric coating refers to a coating made of a polymeric material which may include, without limitation, any type of a photoresist (which, in some cases, may be a combination of polymer, sensitizer, mixer, and other materials) or a polymer. Further, the term “substrate” is used in a broad sense to refer to any component with a relatively flat surface onto which a coating (e.g., a polymeric coating) can be applied, whether uniformly, in patches, or within specific regions. For example, a substrate may include a plate, a panel, a semiconductor wafer, a wafer containing multiple IC structures or devices, a single IC device, or a part (e.g., ceramic, organic, metallic, etc.) with one or more coatings applied to its surface.

Unless otherwise defined, all terms of art, notations, and other scientific terms or terminology used herein have the same meaning as is commonly understood by one of ordinary skill in the art to which this disclosure belongs. Some of the components, structures, and/or processes described or referenced herein are well understood and commonly employed using conventional methodology by those skilled in the art. Therefore, these components, structures, and processes will not be described in detail. All patents, applications, published applications and other publications referred to herein as being incorporated by reference are incorporated by reference in their entirety. If a definition or description set forth in this disclosure is contrary to, or otherwise inconsistent with, a definition and/or description in these references, the definition and/or description set forth in this disclosure controls over those in the references that are incorporated by reference. None of the references described or referenced herein is admitted as prior art to the current disclosure.

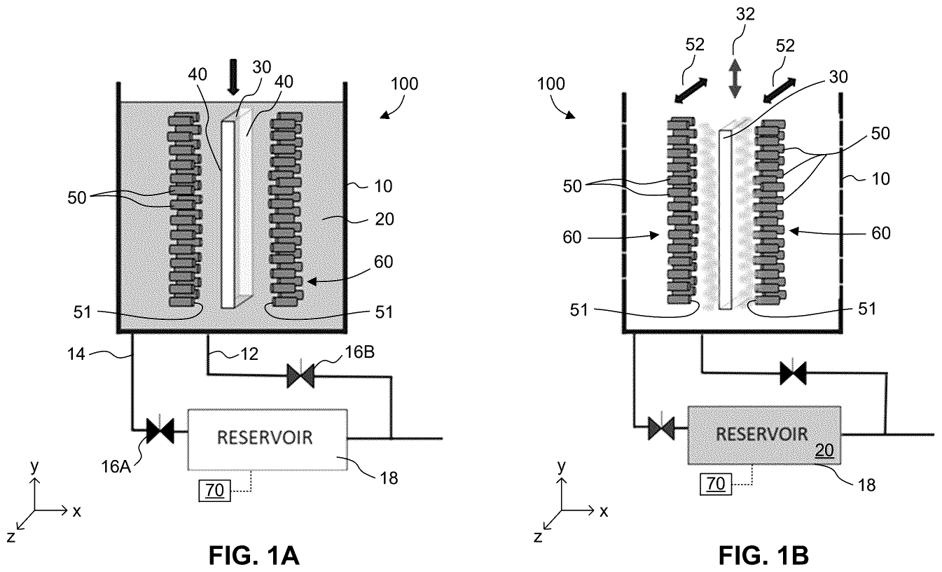

FIGS. 1A and 1B provide schematic illustrations of an exemplary coating removal system 100 (referred to as system 100) described in this disclosure. The system includes a bath or a wet processing tank 10 designed to hold a liquid solvent or composition (referred to as chemical 20). One or more substrates 30, coated with a polymeric material such as a photoresist 40, can be inserted into the tank 10 and immersed in the chemical 20. The substrates 30 may be partially or fully submerged (e.g., at least partially) in the chemical 20 during immersion. It should be noted that chemical 20 may also be referred to as a stripping solution or solvent, chemical stripping agent, stripping solution, etchant solution, etc.

While FIGS. 1A and 1B depict a single substrate 30, this is merely illustrative; in practice, multiple coated substrates 30 can be inserted into the tank 10 simultaneously. Additionally, the illustration shows substrate 30 coated with photoresist 40 on two opposite surfaces, but this is also for demonstration purposes. Any external surface (e.g., sides, edges) or internal surface (e.g., sides of structures or inside structures formed on the substrate) may be coated with photoresist 40. The tank's dimensions and the volume or level of the chemical 20 are configured to ensure that the photoresist 40 coating on the substrate 30 is at least partially submerged in the chemical 20.

Any liquid composition designed to aid in the removal of photoresist 40 from the surface of substrate 30 can be used as chemical 20. The specific type and composition of chemical 20 may vary depending on the application, such as the type of photoresist 40, its thickness, or the substrate 30 to which it is applied. For instance, chemical 20 may include one or more of the following: Tetra-Methyl Ammonium Hydroxide (TMAH), acetone, N-Methyl-2-pyrrolidone (NMP), Dimethyl Sulfoxide (DMSO), Piranha Solution (a mixture of concentrated sulfuric acid (H₂SO₄) and hydrogen peroxide (H₂O₂)), methanol, or Isopropyl Alcohol (IPA), among others. The choice of chemical depends on the specific requirements of the substrate, the type of photoresist, and the overall semiconductor fabrication process. It is important to note that these examples are merely illustrative, and chemical 20 may include any liquid suitable for the intended process in tank 10.

The tank 10 is equipped with an inlet 12 designed to introduce the chemical 20 into the tank 10 from a reservoir 18, and an outlet 14 designed to remove (or drain) the chemical 20 from the tank 10 back into the reservoir 18. As shown in FIGS. 1A and 1B, the chemical 20 is directed into the tank 10 through the inlet 12 (from the reservoir 18) via valve 16A, while the chemical 20 is drained from the tank 10 through the outlet 14 via valve 16B. During the filling process, valve 16A remains open while valve 16B stays closed. Once the tank 10 is filled with the desired amount of chemical 20, valve 16A is closed to keep the chemical inside the tank. After the coated substrates 30 are immersed in the chemical 20 and treated for the specified duration as described below, valve 16B is opened to drain the chemical 20 back into the reservoir 18.

The fluid circuit depicted in FIGS. 1A and 1B merely serves as an example. In general, the chemical 20 may be directed to and from the tank 10 from any location and by any method. In certain embodiments, the fluid circuit may also include supplementary components designed for the specific process taking place within tank 10. These components could include filters to prevent separated photoresist particles (or debris) from flowing back into reservoir 18, macerators to break down larger pieces of debris in the tank 10, pumps to circulate the chemical 20 within the tank 10, sensors to detect the conditions (e.g., particulate contamination, temperature, pressure, pH, conductivity, etc.) in system 100, or heaters and coolers to regulate the temperature of the chemical 20 in the tank 10, among other possibilities.

In some embodiments, tank 10 may also include a bubbler or sparger configured to release a gas into the chemical 20 in tank 10. For example, a gas (e.g., nitrogen gas, carbon dioxide gas, etc.) bubbles may be introduced into the chemical 20 in tank 10 through a bubbler or a sparger to create agitation of the chemical 20. A sparger works by injecting a gas into the chemical 20 through a series of small openings or injection points. The gas bubbles rise to the surface of the chemical 20 in tank 10 and transfer their buoyancy to the chemical 20 thereby promoting mixing of the chemical 20. Alternatively, or additionally, in some embodiments, tank 10 may include mechanical agitators (such as, e.g., impellers or paddles) to agitate the chemical 20 in the tank 10.

The shape and size of the tank 10 can vary depending on the specific application and the dimensions of the substrate 30. Although not a requirement, tank 10 may have a rectangular, square, or a cylindrical shape. Regardless of its shape and size, tank 10 may have a volume, bounded by sidewalls and a bottom surface (or tank floor) that contains the chemical 20. Tank 10 may be made from any material(s) (e.g., high-density polyethylene, polyvinyl chloride, stainless steel with coatings, Teflon, etc.) that are suitable for the process being carried out in tank 10 and resistant to the chemical 20.

In some embodiments, the bottom surface of the tank 10 (or the tank floor) is sloped or inclined (not shown) to facilitate the efficient collection and removal of debris (or particles of photoresist) that accumulates in the tank 10 during the photoresist removal process. The inclined bottom surface may direct the debris towards the lowest point of the tank 10 which may serve as a debris collection area. For example, gravity and liquid flow pattern in the tank 10 may cause the heavier debris to settle and slide down the inclined tank floor surface towards the debris collection area from where it may be removed. In some embodiments, the angle of inclination of the tank floor may be between about 4-15 degrees. In some embodiments, the tank floor may be configured to minimize resistance to the sliding of debris or to minimize debris from getting stuck as it slides towards the collection area. Commonly-assigned U.S. patent application Ser. No. 18/765,916, filed Jul. 8, 2024, describes additional details of the tank 10. This application is incorporated by reference herein in its entirety.

When the coated substrate 30 is immersed in the chemical 20 within tank 10, a reaction between the chemical 20 and the photoresist 40 causes the photoresist 40 to swell. This swelling disrupts the physical structure of the photoresist, facilitating the penetration of the chemical 20 and weakening the bond between the photoresist and the underlying substrate surface. With prolonged exposure to the chemical 20, the bonds break, causing the photoresist coating to begin lifting or peeling off the substrate. The detached resist material collects in the tank 10. While simply immersing the photoresist-coated substrate 30 in the chemical 20 can eventually strip the photoresist 40, this process is time-consuming and may not be efficient for high-volume manufacturing environments.

In embodiments of the present disclosure, as illustrated in FIG. 1B, after the substrate 30 coated with the photoresist 40 is submerged in the chemical 20 (as illustrated in FIG. 1A) for a preset duration, an array 60 of nozzles 50 is employed to spray the chemical 20 onto the photoresist-coated surface of the substrate 30. The array 60 may include any number of nozzles 50 with the outlet end 51 of each nozzle 50 facing the substrate 30. The duration of time for which the substrate 30 is submerged depends on the application (e.g., characteristics of photoresist, substrate, chemical, etc.). This spraying action accelerates and enhances the removal of the photoresist coating from the substrate surface, making the process quicker and more efficient.

In some embodiments, the substrate 30 may be kept immersed in the chemical 20 (or presoaked in the chemical 20) for a period of time ranging from about 1 to 60 minutes (or between about 5 to 30 minutes in some embodiments) before the nozzles 50 begin spraying the chemical 20 onto the substrate surface. As shown by arrow 32 in FIG. 1B, the substrate 30 may be moved back and forth (or mechanically agitated or reciprocated) while being sprayed with the chemical 20 by the array of nozzles 50. Although FIG. 1B depicts the substrate 30 moving vertically (e.g., up and down), this is merely an example, and the substrate 30 could be moved in any direction (e.g., side to side, etc.).

Alternatively, or additionally, the array 60 (of nozzles 50) may be moved back and forth during the spraying process. For example, the nozzles 50 could be moved side to side during spraying. In some embodiments, all nozzles 50 of the array 60 may be moved back and forth together as a single unit. In some embodiments, at least some individual nozzles 50 of the array 60 may be configured to move back and forth independent of other nozzles 50 of the array 60. The back-and-forth movement of either the substrate 30 or the nozzles 50 can increase the surface area exposed to the chemical 20, thereby enhancing the removal of the photoresist coating.

In some embodiments, the chemical 20 may be sprayed onto the photoresist-coated surface of the substrate (from the outlet end 51 of each nozzle 50) while the substrate 30 is immersed in the chemical 20 within the tank 10. Spraying the chemical 20 onto the photoresist coating during immersion can improve the removal process by enhancing the interaction between the chemical and the coated surface. Specifically, spraying creates a dynamic, directed flow of the chemical across the coated surface, ensuring better contact with areas that might be difficult to reach through immersion alone.

Additionally, spraying provides more uniform coverage of the coated surface, allowing the photoresist to break down more evenly. This is especially advantageous when removing photoresist coatings from patterned areas of a substrate, where immersion may not effectively reach all areas (e.g., shadows of structures). The spraying process also facilitates the renewal of the chemical 20 by continually moving fresh etchant over the surface, while removing spent chemical and debris more efficiently. This ensures that the substrate is always exposed to fresh etchant, speeding up the removal process and preventing re-deposition of the photoresist. Furthermore, the spraying may introduce mechanical agitation, aiding in the detachment of the photoresist coating from the substrate. In summary, spraying the chemical enhances both the speed and efficiency of the coating removal by improving coverage, chemical interaction, and mechanical agitation, compared to using immersion alone.

In some embodiments, after presoaking the substrate 30 in the chemical 20 (within the tank 10) for a predetermined duration (see FIG. 1A), the tank 10 may be drained of the chemical 20 before the spraying process begins through the nozzles 50 (see FIG. 1B). For example, after allowing the photoresist-coated substrate 30 to soak in the chemical 20 for a specified time, which causes the photoresist 40 to swell and weaken, valve 16A can be opened to drain the chemical 20 into the reservoir 18 before spraying the chemical 20 onto the substrate's coated surface through the nozzles 50.

Spraying the chemical 20 onto the weakened photoresist coating significantly enhances the effectiveness of photoresist removal compared to simply immersing the substrate in the chemical 20 within the tank 10. The spraying process creates a dynamic, controlled flow of the chemical, improving its interaction with the coating. This ensures that the chemical etchant reaches all areas of the substrate, including hard-to-reach locations that might not be adequately exposed during immersion. Furthermore, spraying ensures more uniform coverage across the coating, allowing for more consistent breakdown and removal. The spraying action also guarantees continuous application of fresh chemical 20 to the coated surface, while spent chemical and debris are efficiently removed, preventing saturation and preserving the effectiveness of the chemical etchant. This continuous replenishment speeds up the removal process. Additionally, the mechanical agitation produced by spraying aids in dislodging the photoresist coating more effectively, facilitating its separation from the substrate 30. As a result, spraying the chemical 20 on the pre-weakened photoresist coating enhances both the speed and efficiency of the coating removal compared to immersion alone.

In some embodiments, the spraying of the chemical 20 onto the substrate surface through the nozzles 50 may continue for a predetermined amount of time, which varies depending on the specific application (e.g., the characteristics of the photoresist, the duration of the substrate's presoaking, etc.). While not mandatory, in some embodiments, the duration for spraying the chemical 20 through the nozzles 50 may range from about 1 to 60 minutes. For instance, in one example, after the coated substrate is presoaked in the chemical 20 for approximately 10-15 minutes, the chemical 20 is sprayed for about 5-10 minutes.

Although the photoresist-coated substrate is described as being sprayed with the same chemical (i.e., chemical 20) that it is immersed in, this is not a requirement. For instance, in some embodiments, the coated substrate may be immersed in a tank containing a first liquid (e.g., a chemical etchant) for a specific amount of time, and then sprayed with a different second liquid for another set period. The choice of the first and second liquids depends on the specific application. For example, in some cases, the first liquid may be TMAH, while the second liquid could be any one of acetone, NMP, DMSO, Piranha Solution, methanol, IPA, or water.

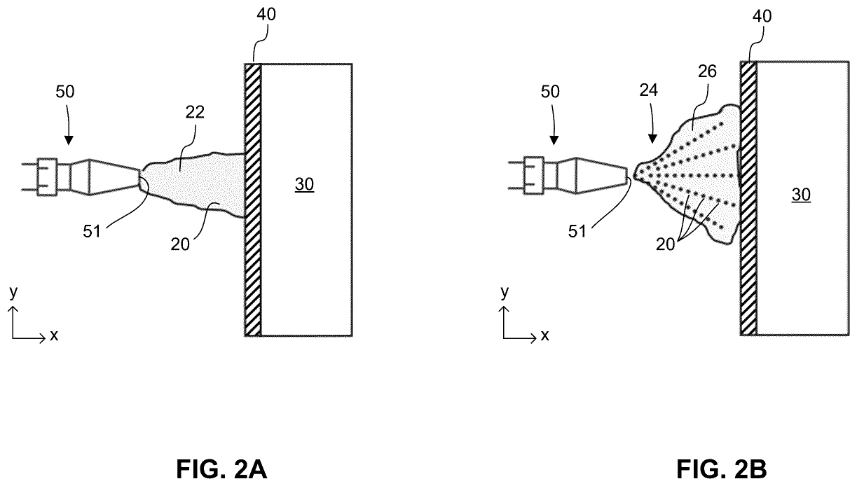

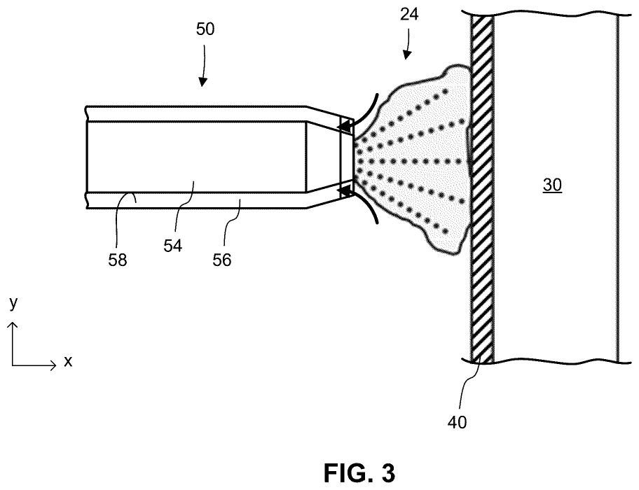

In some embodiments, as illustrated in FIG. 2A, a liquid stream 22 of the chemical 20 is directed from the outlet end 51 of each nozzle 50 (of the nozzle array) to impact the photoresist-coated surface of the substrate 30. In other embodiments, as illustrated in FIG. 2B, an aerosol 24 composed of the liquid chemical 20 dispersed in a gas 26 is directed to the coated surface. A “liquid stream” and an “aerosol” differ significantly in their composition and how they interact with the photoresist-coated surface. The liquid stream 22 consists of a continuous flow of the chemical 20, that impacts or impinges on a focused area of the coated surface. It is delivered as a bulk liquid, without significant dispersion or breakup into smaller droplets, which results in a concentrated and direct application of a stream of the liquid chemical 20 to the treated area. However, this method may not provide even coverage on larger or more intricate surfaces. In contrast, an aerosol 24 is made up of fine droplets of the liquid chemical 20 suspended in a gas 26, creating a mist or cloud that is more evenly dispersed across the coated surface. The gas 26 in the aerosol 24 aids in distributing the droplets evenly and reaching difficult or complex surface geometries, making it especially suitable for surfaces with intricate features or areas that are harder to access.

The interaction of the liquid stream 22 with the coated surface is more direct, allowing the chemical 20 to act on the photoresist 40 in a focused manner. However, this precision can lead to uneven coverage or saturation in certain areas, requiring more chemical 20 for thorough exposure. On the other hand, the aerosol 24 may provide better overall surface coverage, with the added benefit of mechanical agitation from the gas 26. This may help to dislodge the photoresist 40 more effectively and ensure more uniform etching. As a result, in some embodiments, the aerosol 24 may be more efficient and use less chemical 20 while still covering a larger area and providing better consistency in the photoresist removal process. In summary, while the liquid stream 22 offers precision and may be more effective for the removal of photoresist 40 from localized areas of the substrate 30, utilizing an aerosol 24 spray may provide enhanced surface coverage, uniformity, and efficiency by using smaller droplets dispersed through a gas 26, improving the interaction and removal of photoresist 40 from the substrate 30.

Spraying a photoresist-coated surface of a substrate 30 with an aerosol 24 (which comprises a pressurized stream of the chemical 20 dispersed in a gas) may offer several advantages over using a liquid stream 22 for photoresist removal. The gas 26 component in the aerosol 24 improves coverage by dispersing the liquid chemical 20 more evenly across the surface, ensuring better penetration into hard-to-reach areas, especially in intricate patterns or microscopic grooves. The aerosol 24 also creates mechanical agitation, which aids in dislodging the photoresist 40 more efficiently by providing a gentle scrubbing effect, enhancing the rate of detachment without damaging delicate patterns. Additionally, spraying the aerosol 24 accelerates photoresist removal by maintaining continuous movement of the chemical 20, preventing saturation and improving the etching effectiveness. It may also reduce chemical consumption, as the aerosolized chemical 20 is distributed more effectively, leading to less usage of chemical 20 while achieving the same or better results.

The precision of aerosol spraying may also allow for better control of the photoresist removal process, minimizing the risk of damaging the substrate 30. Furthermore, the gas 26 component of the aerosol 24 helps remove debris and spent chemicals from the substrate 30, leading to a cleaner surface with fewer residues compared to liquid spraying. Overall, the aerosol technique combines the benefits of liquid etching with enhanced distribution, agitation, and efficiency, resulting in faster, more uniform, and cost-effective photoresist removal.

An aerosol 24 of the chemical 20 may be formed in any known manner. Typically, an aerosol 24 is created by atomizing the liquid chemical 20 into fine droplets and dispersing them in a suitable gas 26 (e.g., nitrogen, carbon dioxide, etc.). This process can be achieved through various known methods, depending on the desired droplet size and the application. For example, in pressure atomization, the chemical 20 is pressurized and forced through the nozzle 50 to break the liquid chemical 20 into small droplets and create a mist. Ultrasonic atomization, uses high-frequency sound waves to break the chemical 20 into fine droplets. Mechanical atomization (also called jet or pneumatic atomization) involves forcing the liquid chemical 20 through the nozzle 50 under pressure, where it breaks up into droplets due to turbulent flow and gets dispersed in a gas. Electrostatic atomization applies an electric charge to the chemical as it exits the nozzle 50, causing it to break into droplets due to electrostatic forces, providing precise control over droplet size. Thermal atomization involves heating the chemical 20 to vaporize it and then rapidly cooling the vapor, which condenses into droplets. The above described methods are merely exemplary and any known method may be used to create the aerosol 24. Each of these methods aims to break the liquid chemical 20 into small droplets and disperse them in a gas 26.

The characteristics of the aerosol 24 are influenced by several parameters. Propellant kinetic force (pressure) determines the initial velocity and energy of the aerosol particles, affecting their size and distribution. The ratio of gas 26 to the chemical 20 controls the concentration and consistency of the aerosol 24, with higher gas ratios producing finer sprays. Residency time, or the time the aerosol spends in the delivery path, impacts the homogeneity and stability of the aerosol mixture. Chemical and propellant temperatures affect the volatility and evaporation rate, influencing particle size and aerosol density. The volumetric flow rate of the carrier gas 26 dictates the dispersion and delivery rate of the aerosol, impacting its spread and coverage. The type of chemical 20 (e.g., an etchant or rinse water) determines the composition and functionality of the aerosol, such as its reactivity or cleaning efficiency. Together, these parameters allow precise control over the formation and delivery of the aerosol 24.

Any nozzle capable of creating and/or directing an aerosol 24 onto the photoresist-coated surface of the substrate 30 may be used as nozzle 50. In some embodiments, an aerosol 24 may be generated outside of nozzle 50 (e.g., outside tank 10, outside system 100, etc.) and fed into it, with the nozzle then directing the aerosol 24 onto the substrate surface. In other embodiments, both the chemical 20 and the gas 26 may be supplied to the nozzle 50, which then generates and directs the aerosol 24 onto the substrate surface.

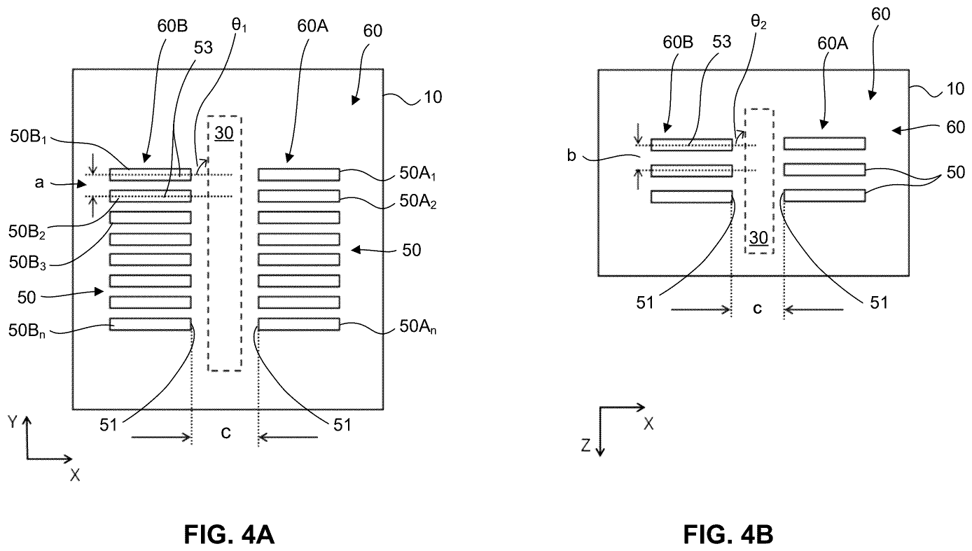

FIG. 3 depicts an example nozzle 50 designed to direct an aerosol 24 onto the photoresist-coated substrate surface. The nozzle 50 consists of a coaxial inner conduit 54 and an outer conduit 56, which together define an annular passageway 58 between them. The inner conduit 54 is responsible for directing the aerosol 24 toward the substrate surface. Upon impact, the liquid droplets (of chemical 20) within the aerosol 24 transition from their dispersed form into liquid, where they interact with the photoresist 40 and assist in its breakdown. The remaining aerosol, along with the gas component, dissipates into the surrounding environment within the tank 10. The annular passageway 58, located between the inner and outer conduits, can be connected to a vacuum pump to create suction, which helps remove the spent vapor from the tank 10. In some embodiments, the liquefied portion of the aerosol 24 may also be evacuated through this passageway. Alternatively, or additionally, the liquidized portion can flow out of the tank 10 and into the reservoir 18 via outlet 14 (see FIGS. 1A and 1B).

In the following discussion, the term “fluid stream” is used to collectively encompass both a liquid stream (22) and an aerosol stream (24). The nozzle of FIG. 3 is merely exemplary. Nozzle 50 may have any configuration that is capable of directing a fluid stream (a liquid stream 22 or an aerosol 24) to the substrate surface. Co-assigned Patent No. U.S. Pat. No. 12,138,745 and patent application Ser. No. 18/811,061 , filed Aug. 21, 2024, describe some suitable nozzles that may be used in embodiments of the current application. These references are incorporated by reference in their entirety.

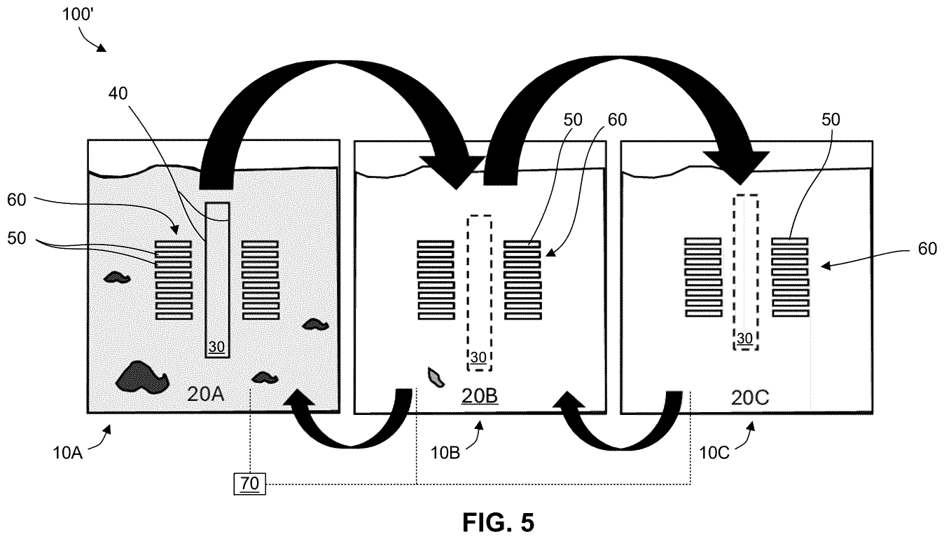

Referring to FIGS. 1A and 1B, the nozzle array 60 can consist of any number of nozzles 50 arranged in various patterns. FIGS. 4A and 4B provide an example of a nozzle arrangement within a tank 10. FIG. 4A shows a side view (in the XY or vertical plane) of the tank 10, while FIG. 4B presents a top view (in the XZ or horizontal plane). In the embodiment depicted in FIGS. 4A and 4B, the array 60 is a rectangular configuration of nozzles 50, arranged in a grid-like pattern of rows and columns in both vertical and horizontal planes. Specifically, array 60 features a 2-column structure in both the vertical and horizontal planes, with 8 rows of nozzles in the vertical plane (see FIGS. 4A) and 3 rows in the horizontal plane (see FIG. 4B). This arrangement is described as an 8×2 array (rows×columns) in the vertical plane and a 3×2 array in the horizontal plane. Generally, arrays 60 can include any number of rows and columns of nozzles, allowing for flexible configurations.

In certain embodiments of the present disclosure, the nozzles are arranged in a 2-column array (e.g., columns 60A, 60B) in both the vertical and horizontal planes, with any number of nozzles distributed across rows (i.e., an x×2 array, where x represents the number of rows). The number of rows (x) may vary depending on the application, such as the size of the substrate being treated. For instance, if the substrate 30 in tank 10 is a large panel, the array may include a higher number of rows, typically between 8 and 20. The two columns 60A, 60B of nozzles 50 in the array are positioned such that the outlet ends 51 of the nozzles in each column face each other. A gap or spacing (c) between the outlet ends 51 is maintained to accommodate the placement of a substrate. In some embodiments, this gap (c) may be less than or equal to about 260 mm. For example, gap (c) may range between approximately 0 -260 mm (or 0 -300 mm in some embodiments). When the nozzles 50 are activated, the fluid stream (such as a liquid stream 22 or an aerosol 24) emitted from the outlet end 51 of each nozzle impinges on the surface of the substrate. Although the gap (c) between the nozzles 50A₁-50Aₙ in column 60A and the nozzles 50B₁-50Bₙ in column 60B is depicted as constant, this is merely an example. In some embodiments, the gap (c) between different pairs of nozzles can vary. For instance, the gap (c) between nozzles 50A₁ and 50B₁ may have one value, while the gap (c) between nozzles 50Aₙ and 50Bₙ may have a different value.

The spacing between nozzles 50 in each row can vary depending on the specific application, such as the size of the substrate 30 or the characteristics of the photoresist 40. In some embodiments, the spacing or pitch (a) between nozzles in the vertical plane (refer to FIG. 4A) may range from approximately 20-50 mm (or 20-60 mm in some embodiments). Similarly, the pitch (b) between nozzles in the horizontal plane (refer to FIG. 4B) may be between about 20-250 mm (or 20-300 mm in some cases). In certain embodiments, the pitch (a) in the vertical plane and the pitch (b) in the horizontal plane may be equal, resulting in the nozzle openings 51 forming a square grid within the substrate's plane (i.e., the YZ plane). The arrangement of nozzle openings 51 in a square grid (in the YZ plane) is not mandatory. In some embodiments, the nozzle openings 51 may be arranged in a rectangular grid. Additionally, other configurations, such as circular, elliptical, random, or similar patterns, are also possible.

In certain embodiments, the number of nozzles 50 in the array 60 may be configured so that the nozzle openings 51 substantially cover the entire area of the substrate 30 when viewed in the YZ plane (the plane of the substrate 30). For instance, if the substrate 30 is a 210 mm×210 mm panel and the vertical pitch (a) and horizontal pitch (b) of the nozzles 50 are both 20 mm, then 11 nozzles (i.e., 200/20+1) can be arranged in both the vertical plane (XY plane) and the horizontal plane (XZ plane). This configuration ensures that, in the YZ plane, the nozzle openings 51 effectively cover nearly the entire substrate area.

While pitches (a) and (b) in the vertical and horizontal planes are illustrated as constant, this is not a strict requirement. In some embodiments, the pitch between nozzles in the vertical and/or horizontal planes may vary. For instance, the pitch (a) between nozzles in different columns, such as 60A and 60B, may differ. For example, the pitch (a) between nozzles 50A₁-50Aₙ could differ from the pitch (a) between nozzles 50B₁-50Bₙ. Similarly, the pitch (a) between nozzles within the same column may vary—for instance, the spacing between nozzles 50A₁ and 50A₂ could be one value, while the spacing between nozzles 50A₂ and 50A₃ could be another. Likewise, the pitch (b) between nozzles in the horizontal plane may also vary, such as between columns 60A and 60B or within a single column 60A or 60B.

The nozzles 50 in the array 60 are arranged in certain embodiments such that the longitudinal axis 53 of each nozzle is substantially perpendicular to the substrate surface in both the vertical and horizontal planes (e.g., θ₁ and θ₂≈90°). When the longitudinal axis 53 of a nozzle 50 is substantially perpendicular to the substrate surface, the fluid stream emitted from the nozzle impacts the substrate surface at a substantially perpendicular angle. As explained previously, “substantially” perpendicular means that an angle is very close to 90 degrees but may not be exactly 90 degrees due to deviations caused by practical real-world effects (tolerance stack up, environmental factors such as temperature variations, vibration, etc.).

In certain embodiments, the longitudinal axis 53 of a nozzle 50 may be inclined with the substrate surface the vertical or horizontal planes. The term “inclined” is used to indicate that the longitudinal axis 53 is angled at a non-perpendicular (and non-parallel) angle, or slanted, with respect to the substrate surface (e.g., θ₁ or θ₂≠90° or 0°). In other words, when the longitudinal axis 53 of the nozzle 50 is inclined with the substrate surface, it makes an acute or obtuse angle the surface. In this disclosure, referring to a nozzle 50 as inclined relative to (or substantially perpendicular to) the substrate surface means that the longitudinal axis 53 of the nozzle 50 is angled relative to (or aligned nearly perpendicular to) the substrate surface.

In some embodiments, a nozzle 50 is inclined to the substrate surface in one or both the vertical and horizontal planes (e.g., θ₁ or θ₂≠90° and 0°). In other words, the longitudinal axis 53 may be substantially perpendicular to the substrate surface in one plane (e.g., the vertical plane, where θ₁≈90°) while being inclined with the substrate surface in the other plane (e.g., the horizontal plane). Alternatively, in some embodiments, the longitudinal axis 53 of a nozzle 50 may be inclined in both the vertical and horizontal planes.

When a nozzle 50 is inclined with the substrate surface, an inclined fluid stream impacts the substrate surface. An inclined fluid stream may improve surface coverage and enhance photoresist removal by allowing the chemical to reach shadowed areas, such as undercut regions, cavities, or edges of patterns. An angled impact may also create a shearing effect with a tangential force component that aids in mechanically lifting and breaking down the photoresist layer, leading to improved delamination. Furthermore, an angled stream may exert less localized pressure on delicate substrates and distribute the force more evenly and minimize damage. An angled stream may also enhance turbulence on the surface, improving the chemical's reaction with the photoresist, resulting in faster and more thorough stripping.

In some embodiments, the angle of inclination (e.g., θ₁ or θ₂) of the nozzles 50 may be varied. For example, the nozzles 50 of the array 60 may be adjusted such that the inclination angle of a nozzle 50 (e.g., the angle that the longitudinal axis 53 of a nozzle 50 makes with the substrate surface—θ₁ or θ₂) is changed from a first value to a second value. In some embodiments, the inclination of the nozzles 50 (θ₁ or θ₂) may be varied between about 45-90 degrees. For example, at the onset of spraying, a nozzle 50 may be substantially perpendicular to the substrate surface (e.g., θ₁ and θ_{2≠90}°). As spraying progresses, the inclination of the nozzle 50 may be adjusted such that θ₁ or θ₂ is non-perpendicular.

In some embodiments, when the inclination of the nozzles 50 in an array 60 is adjusted, the inclination of all nozzles in the array changes simultaneously. In other embodiments, the inclination of individual nozzles, or a specific set of nozzles within the array 60, can be adjusted independently. For instance, with reference to FIGS. 4A and 4B, the inclination of nozzle 50A₁ can be modified without affecting the inclination of other nozzles in the array. Alternatively, or additionally, the inclination of all nozzles 50A₁-50Aₙ in column 60A can be adjusted without altering the inclination of nozzles 50B₁-50Bₙ in column 60B. This allows for configurations where, for example, an inclined fluid stream from the nozzles of column 60A impinges on one surface of the substrate, while a substantially perpendicular fluid stream (or a differently inclined fluid stream) impacts the opposite surface of the substrate.

The position of the nozzle array 60 within the tank 10, as well as the spacing between the nozzles 50 (e.g., gap (c), pitch (a), and pitch (b)), can be adjusted similarly to the inclination. For instance, the array 60 can be moved as a single unit in the X, Y, or Z direction, or rotated around the X, Y, or Z axis, thereby altering its location or orientation within the tank. Additionally, the positions of individual nozzles 50 within the array 60 can be modified to change the spacing parameters (e.g., gap (c), pitch (a), and pitch (b)). For example, columns 60A and 60B may be repositioned (e.g., moved closer together or farther apart) to adjust the gap (c) between the sets of nozzles 50A₁-50Aₙ and 50B₁-50Bₙ from one value to another. Similarly, the pitch (a) or pitch (b) of the nozzles can be altered either simultaneously or individually. For instance, the pitch (a) between all nozzles may be uniformly changed from a first value to a second value, or selectively adjusted between specific nozzles (e.g., between 50A₁ and 50A₂) without affecting the pitch (a) of other nozzles. The pitch (b) between nozzles can also be modified in a similar manner, either collectively or selectively.

The inclination and positions of the nozzles, whether individually or collectively, can be adjusted using a variety of known mechanical and electromechanical mechanisms, including both manual and automated systems. Manual methods may involve pivoting mounts that allow nozzle rotation, threaded screws for precise angle adjustments, or slot-and-lock systems enabling the nozzles to slide and securely lock into different positions. Automated systems may use servo motors for accurate, programmable movements or stepper motors for incremental adjustments. Electromechanical actuators, such as linear or rotary actuators, provide automated control of nozzle positioning and inclination. Hydraulic or pneumatic systems, including pistons or compressed air-driven cylinders, enable fluidic adjustments, while cam-driven mechanisms can dynamically alter nozzle angles and positions. Magnetic or electromagnetic systems, such as magnetic mounts or electromagnetic actuators, offer precise control of nozzle positions and inclinations for fine-tuning. Spring-loaded systems, incorporating levers or pre-tensioned springs, allow for quick and reliable adjustments, while robotic systems, such as robotic arms or programmable multi-axis mounts, enable dynamic and precise positioning during operation. Additionally, tool-free mechanisms like snap-and-adjust mounts or ball-and-socket joints provide simple and efficient manual adjustments without the need for specialized tools. These systems collectively ensure flexibility and precision in adapting nozzle positions and angles to suit various operational requirements.

Since the nozzles 50 are located within the tank 10 and submerged in the chemical 20 (see FIG. 1A), they are specifically designed to endure exposure to the chemical 20. In some embodiments, the nozzle 50 may be configured to prevent (or minimize) the ingress of the chemical 20 into its interior. For example, a check valve may be integrated into the nozzle 50 to allow the fluid stream (liquid stream 22 or aerosol 24) to exit while preventing chemical backflow into the nozzle. Dynamic sealing solutions, such as bellows, flexible membranes, or diaphragm seals, may also be used to provide adaptive barriers to chemical ingress. In some embodiments, the nozzle 50 may be maintained at a slightly higher internal pressure than the surrounding chemical 20 to prevent chemical ingress. For example, a gas (e.g., gas 26) may be constantly directed through the nozzle 50 (e.g., into the chemical 20 in tank 10) to maintain positive internal pressure and block chemical ingress.

In some embodiments, a bypass line incorporated in the nozzle 50 may prevent chemical ingress into the nozzle by creating an alternate flow path or maintaining positive internal pressure. By supplying a clean fluid or gas through the bypass line, positive pressure can be maintained within the nozzle, opposing external chemical pressure and blocking ingress. The bypass line can also divert any chemicals that might enter the nozzle to a safe discharge point or back to a tank, preventing them from interior components.

System 100 may also include a controller 70 that manages and regulates the operation of system 100 to achieve desired processing outcomes (e.g., removal of photoresist coating from substrate 30) in tank 10. Controller 70 may be a component or a system (e.g., made of multiple components) that may receive input from different sensors (not shown) in system 100 to monitor process conditions in the tank 10 and manage factors such as, for example, chemical concentration, temperature, flow rates, and other parameters of the chemical 20 entering tank 10 (e.g., from inlet 12) to ensure accurate and consistent processing of the substrates 30 in tank 10. Generally, controller 70 may constitute any physical device or group of devices having electric circuitry that performs a logic operation based on one or more inputs.

For example, controller 70 may include one or more integrated circuit (IC) based processors, such as, for example, microprocessors, application-specific integrated circuit (ASIC), microchips, microcontrollers, central processing unit (CPU), graphics processing unit (GPU), digital signal processor (DSP), field-programmable gate array (FPGA), or other circuits suitable for executing instructions or performing logic operations. The instructions executed by this processor(s) may, for example, be pre-loaded into a memory integrated with or embedded into the controller or may be stored in a separate memory accessible to controller 70. The memory may include a Random Access Memory (RAM), a Read-Only Memory (ROM), a hard disk, an optical disk, a magnetic medium, a flash memory, other permanent, fixed, or volatile memory, or any other mechanism capable of storing instructions and data.

Signals from the sensors (temperature sensors, pressure sensors, pH sensors, conductivity sensors, etc.) of system 100 that indicate the parameters of the chemical 20 in tank 10 may be directed to controller 70. Controller 70 may also include, or have access to, data indicative of the effect of one or more of the monitored parameters on the coating removal process occurring in tank 10. In some embodiments, such data may be stored in a memory of, or accessible to (e.g., operatively connected to), controller 70. As an example, when tank 10 is used for removing a dry resist film coating on a substrate 30, the parameters (temperature, pH, electrical conductivity, etc.) of the chemical 20 in tank 10 (or the chemical content in the fluid sprayed through nozzles 50) may have a significant effect on the coating removal process. Controller 70 may adjust the conditions of the chemical 20 for improved performance. In a similar manner, controller 70 may also monitor, control, and adjust the parameters of the aerosol 24 (e.g., pressure, ratio of gas, etc.) discharged via nozzles 50 of array 60.

In the embodiment shown in FIGS. 1A and 1B, the photoresist removal is performed within a single tank 10. For instance, the photoresist-coated substrate 30 is initially presoaked in the chemical solution 20 contained in tank 10, which causes the photoresist to swell or soften. Subsequently, the chemical 20 is sprayed (in some embodiments, after the chemical 20 in tank 10 has been drained) onto the softened photoresist to detach it from the substrate surface. Alternatively, in some embodiments, a multi-tank system may be employed to progressively remove the photoresist coating from the substrate surface.

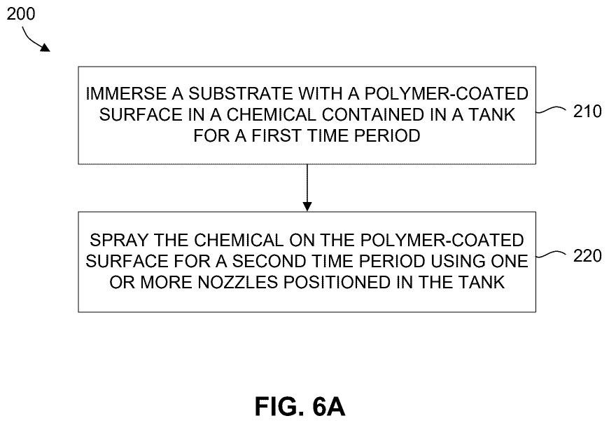

FIG. 5 depicts an exemplary embodiment of a coating removal system 100′ comprising three tanks: 10A, 10B, and 10C. These tanks (and system 100′) may share similarities with tank 10 (and system 100) of FIGS. 1A and 1B, incorporating features such as an array 60 of nozzles 50, controller 70, among others. For conciseness, the shared features will not be re-described in relation to tanks 10A, 10B, 10C, and system 100′ of FIG. 5. In some embodiments, tanks 10A, 10B, and 10C may also perform photoresist coating removal on substrate 30 in a manner similar to tank 10.

For example, the photoresist-coated substrate 30 may first be immersed or presoaked in chemical 20A contained in tank 10A for a predetermined period, softening and weakening the photoresist coating. Following this initial soaking, chemical 20A can be sprayed onto the substrate 30 through an array 60 of nozzles 50 for a second predetermined period, removing at least part of the photoresist coating. The duration of these time periods can vary based on the application requirements. Chemical 20A may be any suitable liquid etchant, and in some embodiments, it may be identical to chemical 20 used in tank 10. As previously mentioned, in some embodiments, chemical 20A may be drained from tank 10A (e.g., into a reservoir) before being sprayed through the nozzles 50. In other embodiments, chemical 20A is not drained from tank 10A prior to being sprayed. Additionally, as described earlier (e.g., with reference to FIGS. 2A and 2B), chemical 20A may be applied to the substrate surface either as a liquid stream 22 or as an aerosol 24.

After spraying chemical 20A onto the substrate surface for the second predetermined time in tank 10A, the substrate 30, still with residual photoresist coating, is transferred to tank 10B. A similar process may then take place in tank 10B to further remove the coating from the substrate surface. For instance, the substrate 30 is presoaked in chemical 20B within tank 10B for a third predetermined time, followed by spraying chemical 20B onto the substrate surface through nozzles 50 for a fourth predetermined time. In some embodiments, the chemical 20B in tank 10B may be drained prior to spraying. The durations of the third and fourth time periods can vary depending on the specific application. Chemical 20B may be any suitable liquid etchant and, in some embodiments, may be the same as chemical 20A or chemical 20. Additionally, as described earlier, chemical 20B may be applied to the substrate surface either as a liquid stream or as an aerosol.

After processing in tank 10B, the substrate 30, with any remaining photoresist coating, is transferred to tank 10C for further treatment. In some embodiments, the substrate 30 is presoaked in chemical 20C contained in tank 10C for a fifth predetermined time, followed by spraying chemical 20C onto the substrate surface (either as a liquid stream or an aerosol) through nozzles 50 for a sixth predetermined time. In some cases, chemical 20C may be drained from tank 10C before spraying. Chemical 20C can be any suitable liquid etchant, and in some embodiments, it may be the same as chemical 20A, 20B, or 20. Alternatively, in some embodiments, chemical 20C may be water, such as deionized water, used to clean the substrate surface after coating removal. In such embodiments, the photoresist coating may be removed from the substrate surface by the processing in tanks 10A and 10B, and the surface may be cleaned in tank 10C.

In some embodiments, the substrate 30 may be immersed in and sprayed with the chemical (as a liquid stream or as an aerosol) only in the first tank (tank 10A). In the subsequent tanks, the chemical may be applied (as a liquid stream or as an aerosol) solely by spraying onto the substrate surface through nozzles. For example, after the substrate 30 is presoaked and sprayed with chemical 20A in the first tank 10A, it is transferred to the second tank 10B. In tank 10B, chemical 20B is sprayed onto the substrate surface to remove additional photoresist. The substrate is then moved to the third tank 10C, where chemical 20C is sprayed onto the surface to remove any remaining photoresist and clean the substrate.

In this three-tank system, the first tank 10A removes an initial thickness of the photoresist coating (e.g., up to 140 microns). Spraying in the second tank 10B further reduces the coating thickness, while spraying in the third tank 10C completes the removal and/or cleans the surface. For example, immersion in the first tank 10A sufficiently weakens the photoresist, enabling complete removal and thorough cleaning through the subsequent spraying steps in the three tanks.

In a multi-tank system 100′, the chemical in an earlier tank may contain more contaminants compared to the chemical in later tanks. For instance, because a greater amount of photoresist coating is typically removed in tank 10A than in subsequent tanks (10B and 10C), chemical 20A in tank 10A may contain more residual photoresist particles (or debris) than chemical 20B in tank 10B and chemical 20C in tank 10C. Similarly, chemical 20B may have more debris than chemical 20C.

In some embodiments, chemicals 20A, 20B, and 20C may be the same substance (e.g., TMAH), and the spent chemical from a later tank may be repurposed for use in an earlier tank. For example, the used chemical 20C from tank 10C may be transferred to tank 10B, and the spent chemical from tank 10B may then be used in tank 10A. The transfer of chemicals between tanks can be managed based on the number of substrates processed or the condition of the chemical in each tank (e.g., pH, conductivity, particulate content). The controller 70 monitors the chemical's condition in the various tanks and facilitates the transfer of chemicals as needed. For instance, each tank 10A, 10B, and 10C may be equipped with one or more filters designed to trap debris, such as photoresist particles separated from the substrate 30, preventing them from exiting the tank. A higher differential pressure across a filter may indicate increased particulate contamination in the tank, which could lead to process inconsistencies (e.g., reduced efficiency in coating removal). The controller 70 can monitor the differential pressure in each tank to assess the level of particulate contamination and, if necessary, initiate the transfer of chemicals between tanks.

The three-tank system described in reference to FIG. 5 is merely an example. In practice, any number of tanks operating in the manner described with reference to FIG. 5 can be used. Furthermore, while the removal of a photoresist coating is discussed as an example, the systems 100, 100′ described in this disclosure can be used to remove a coating of any type of polymeric material (i.e., polymeric coating).

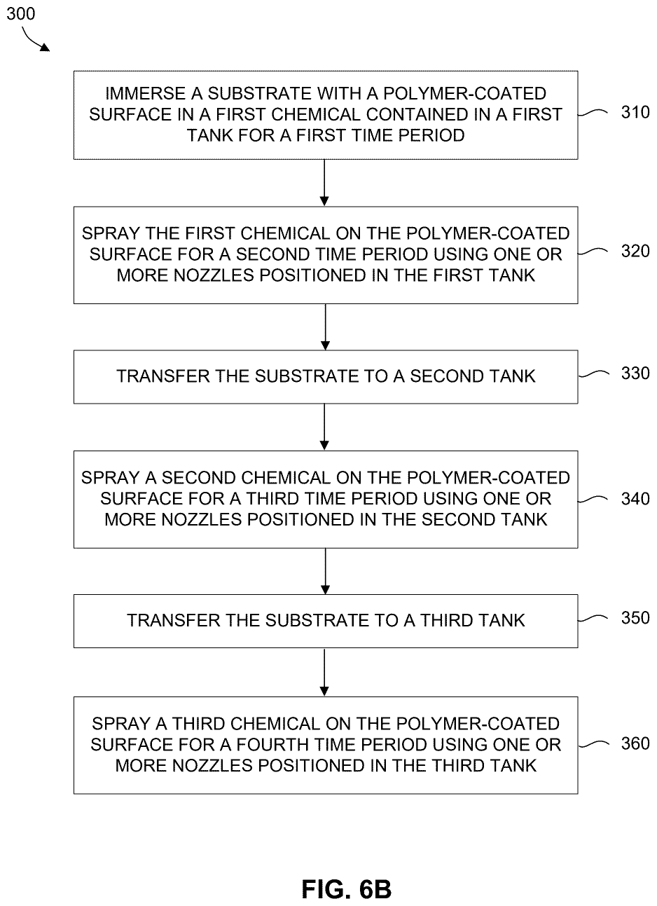

FIG. 6A illustrates a flowchart outlining an exemplary method 200 for removing a polymeric coating using the disclosed system. The process begins with a substrate featuring a polymer-coated surface being placed into a tank and immersed in a chemical solution for an initial first time period (step 210). During this immersion, at least a portion of the polymer-coated surface is submerged, allowing the chemical to weaken the polymeric coating by causing it to swell or soften. After this initial phase, the substrate undergoes a second step (step 220) where its polymer-coated surface is sprayed with the chemical through one or more nozzles positioned within the tank. This spraying, conducted over a specified second time period, can involve either a liquid stream or an aerosol form of the chemical. During this stage, portions of the polymeric coating may detach and be effectively removed from the substrate.

Various modifications can be made to the method described above. For instance, in some embodiments, the substrate may be immersed in one chemical during step 210 and sprayed with a different chemical during step 220. Alternatively, or additionally, the chemical in the tank may be drained after the first immersion period (e.g., following step 210) before initiating the spraying process in step 220.

FIG. 6B presents a flowchart for an exemplary method 300 for removing a polymeric coating using the multi-tank system described in this disclosure. In step 310, a substrate with a polymer-coated surface is placed into a first tank and immersed in a first chemical for an initial period (first time period). During this immersion, the polymeric coating begins to weaken, such as by swelling or softening. Following this, in step 320, the polymer-coated surface of the substrate is sprayed with the same chemical using one or more nozzles positioned within the first tank for a second time period. This spray may be delivered as a liquid stream or an aerosol, during which parts of the polymer may detach and be removed from the substrate.

Next, in step 330, the substrate is transferred to a second tank. In this tank, the polymer-coated surface is sprayed with a second chemical, either in liquid or aerosol form, for a third time period in step 340, further removing polymeric coating from the surface. Finally, the substrate is moved to a third tank in step 350, where a third chemical is applied as a spray, again in liquid or aerosol form, for a fourth time period. This final step, outlined in step 360, is intended to eliminate any residual polymer remaining on the surface and clean the surface.

Various modifications can be applied to the method described above. For instance, in some embodiments, the first, second, and third chemicals may all be the same. In such cases, the chemical used in the third tank can be repurposed for use in the second tank, and the chemical from the second tank can be repurposed for the first tank. Alternatively, in some embodiments, the first and second tanks may contain chemicals specifically designed to strip the polymer from the substrate surface (e.g., TMAH), while the third tank may use water to clean the surface. Additionally, the chemical in the first tank may be drained after the initial immersion period (e.g., following step 310) before beginning the spraying process in step 320. Similarly, in some embodiments, as in step 310, the substrate in the second tank may be immersed in the second chemical for a period before the spraying step (step 340) begins.

It will be appreciated that the embodiments of the present disclosure are not limited to the exact construction that has been described above and illustrated in the accompanying drawings and that various modifications and changes may be made without departing from the scope thereof.

What is claimed is:

1. A system for removing a polymeric coating from a substrate, comprising:
a wet processing tank configured to contain a chemical in liquid form, wherein the wet processing tank is configured to receive at least one substrate having a surface with a polymeric coating such that at least a portion of the polymeric coating is immersed in the chemical; and
a plurality of nozzles positioned in the tank and configured to be immersed in the chemical, wherein each nozzle of the plurality of nozzles is configured to direct a fluid stream of the chemical on the surface to remove at least a portion of the polymeric coating from the surface.

2. The system of claim 1, wherein the plurality of nozzles comprise multiple pairs of nozzles spaced apart from each other, and wherein a fluid outlet of each nozzle of a pair of nozzles of the multiple pairs of nozzles face each other.

3. The system of claim 2, wherein the at least one substrate is configured to be received in a gap between the fluid outlets of the pair of nozzles.

4. The system of claim 3, wherein the gap between the fluid outlets of the pair of nozzles is configured to changed.

5. The system of claim 1, wherein each nozzle of the plurality of nozzles is configured to direct an aerosol of the chemical on the surface.

6. The system of claim 1, wherein each nozzle of the plurality of nozzles is configured to direct a liquid stream of the chemical on the surface.

7. The system of claim 1, wherein each nozzle of the plurality of nozzles is configured to prevent ingress of the chemical contained in the wet processing tank into the nozzle.

8. The system of claim 1, wherein a spacing between two adjacent nozzles of the plurality of nozzles is configured to be changed.

9. The system of claim 1, wherein a spacing between two adjacent nozzles of the plurality of nozzles is configured to be changed without changing the spacing between other adjacent nozzles of the plurality of nozzles.

10. The system of claim 1, wherein the plurality of nozzles are positioned in the tank such that the fluid stream that is configured to emanate from each nozzle impinges on the surface at a substantially perpendicular angle.

11. The system of claim 1, wherein the plurality of nozzles are positioned in the tank such that the fluid stream that is configured to emanate from each nozzle impinges on the surface at a non-perpendicular angle.

12. The system of claim 1, wherein the plurality of nozzles are positioned in the tank such that the fluid stream that is configured to emanate from a first nozzle of the plurality of nozzles impinges on the surface at a first angle and the fluid stream that is configured to emanate from a second nozzle of the plurality of nozzles impinges on the surface at a second angle different from the first angle.

13. The system of claim 1, wherein an angle of inclination of each nozzle of the plurality of nozzles with the surface is configured to be changed simultaneously.

14. The system of claim 1, wherein an angle of inclination of a first nozzle of the plurality of nozzles with the surface is configured to be changed without changing the angle of inclination of a second nozzle of the plurality of nozzles with the surface.

15. A method of removing a polymeric coating from a substrate, comprising:
positioning at least one substrate having a surface with a polymeric coating in a wet processing tank containing a chemical in liquid form such that at least a portion of the polymeric coating is immersed in the chemical and is positioned proximate a plurality of nozzles positioned in the tank; and
directing a fluid stream of the chemical on the surface through the plurality of nozzles to remove at least a portion of the polymeric coating from the surface.

16. The method of claim 15, further comprising draining the chemical from the wet processing tank prior to directing the fluid stream on the surface.

17. The method of claim 15, wherein directing the fluid stream of the chemical includes directing an aerosol of the chemical on the surface.

18. The method of claim 15, wherein directing the fluid stream of the chemical includes directing a liquid stream of the chemical on the surface.

19. The method of claim 15, wherein the chemical includes at least of one of Tetra-Methyl Ammonium Hydroxide, acetone, N-Methyl-2-pyrrolidone, Dimethyl Sulfoxide, Piranha Solution, methanol, or Isopropyl Alcohol.

20. The method of claim 15, wherein the polymeric coating is a photoresist coating.
